(19) United States
(12) Patent Application Publication
(10) Pub. No.: US 2015/0187731 A1
(43) Pub. Date: Jul. 2, 2015

(54) LOW COST CONNECTOR FOR HIGH SPEED, HIGH DENSITY SIGNAL DELIVERY

(71) Applicant: QUALCOMM Incorporated, San Diego, CA (US)

(72) Inventors: Dong Wook KIM, San Diego, CA (US); Kyu-Pyung HWANG, San Diego, CA (US); Chin-Kwan KIM, San Diego, CA (US); Young Kyu SONG, San Diego, CA (US); Hong Bok WE, San Diego, CA (US)

(73) Assignee: QUALCOMM Incorporated, San Diego, CA (US)

(21) Appl. No.: 14/141,342

(22) Filed: Dec. 26, 2013

(51) Int. Cl. H01L 25/065; H01L 23/00; H01L 25/00

(52) U.S. Cl. CPC H01L 25/0655; H01L 25/50; H01L 24/17; H01L 24/50; H01L 24/73; H01L 24/81; H01L 24/86; H01L 2224/73211; H01L 2224/73261; H01L 2224/86815; H01L 2224/86203; H01L 2224/81203; H01L 2224/81815; H01L 2924/01029; H01L 2924/07025

(57) ABSTRACT

A high-speed, high-density Input/Output bridge couples dies on a substrate to each other using a flexible connector that is attached to the substrate using solder balls disposed in openings in the substrate. Thus, the bulky, male-to-female connectors and/or silicon bridges are eliminated while still permitting dies disposed on the substrate to be coupled together.

### FIELD OF DISCLOSURE

Aspects of the present disclosure relate generally to semiconductor packaging, and in particular to semiconductor packaging that implements a low cost connector for high speed, high density signal delivery.

### BACKGROUND

One typical conventional multi-chip system includes a printed circuit board (PCB) on which two or more package substrates are mounted. One die is mounted on one package substrate and another die is mounted on the other package substrate. Input/Output (I/O) signals from the dies need to be routed to each other, to the package substrates, and to the printed circuit board (PCB).

In these types of conventional multi-chip systems, the high speed input/output signals that connect the dies, package substrates, and the printed circuit board (PCB) to each other go through numerous vias, solder balls, plated through holes, etc., in the package substrate and the printed circuit board (PCB). These multi-chip systems tend to work well; however, the number Input/Output (I/O) signals counts and data rates that need to be supported by the multi-chip systems are increasing as these system evolve to higher performances, such as 10 Gbit and higher data rates, without signal losses.

To achieve this higher performance, Input/Output (I/O) signals lines that have small pitches are used to route the Input/Output (I/O) signals lines. Integrating the smaller-pitched connectors into the system so that signal traces on the cable are aligned with signal traces on the package substrates can be challenging. Misalignment can result in signal discontinuities and/or impedance matching issues in the system. Moreover, this arrangement requires that a plug and receptacle be added to the bill of materials. The plug and receptacle also add to the bulk of the cable.

Another typical conventional multi-chip system includes one chip that is mounted in a chip socket, and one or more other chips mounted in one or more other chip sockets. Both chip sockets are mounted on a motherboard. The chip sockets each have a receptacle for a flexible cable. The flexible cable is connected to the receptacles to couple Input/Output (I/O) signals between the two chips. This arrangement also suffers from signal discontinuities and adds a plug and receptacle to the bill of materials. This arrangement also requires additional space on the substrate.

Still another typical conventional multi-chip system includes a substrate into which an opening is etched so that a bridge (e. g., silicon bridge) can be formed to connect two dies together. This arrangement also suffers from alignment issues, signal discontinuities, and requires that a silicon bridge be added to the bill of materials.

Each of these arrangements also requires multiple process steps to during manufacture. Thus, improved apparatuses and methods for improving alignment and reducing signal discontinuities are needed.

### SUMMARY

Example implementations of the technology described herein are directed to apparatuses, systems, methods, and computer-readable media for a low cost connector capable of delivering high speed, high density signals. In one or more implementations, a flexible connector for delivery of high speed, high density signals to a device includes an insulating material and interconnects disposed in the insulating material. The interconnects are configured to mate the flexible connector in openings disposed in a substrate using solder balls.

In one or more alternative implementations, a semiconductor device assembly includes a flexible connector having an insulating material and interconnects disposed in the insulating material. A substrate is coupled to the flexible connector. The substrate includes solder balls disposed therein. The interconnects are configured to mate the flexible connector with openings disposed in the substrate using solder balls.

In still another implementation, a method of manufacturing a semiconductor device assembly comprises providing a flexible connector having an insulator and interconnects disposed in the insulator. The method further comprises mating the flexible connector to openings in a substrate using at least one of tape automated bonding, reflow, and thermo-compression. A non-transitory computer-readable media may implement one or more methods described herein.

### BRIEF DESCRIPTION OF THE DRAWINGS

The accompanying drawings are presented to aid in the description of the technology described herein and are provided solely for illustration of the implementations and not limitation thereof.

FIG. 1 is a cross-sectional representation of a flexible connector according to one or more implementations of the technology described herein.

FIG. 2 is a cross-sectional representation of a semiconductor device having the flexible connector depicted in FIG. 1 according to one or more implementations of the technology described herein.

FIG. 3 is a flowchart illustrating a method of making the semiconductor device depicted in FIG. 2 according to one or more implementations of the technology described herein.

### DETAILED DESCRIPTION

In general, the subject matter disclosed herein is directed to systems, methods, apparatuses, and computer-readable media for a high-speed, high-density Input/Output bridge that couples dies on a substrate to each other. In one or more implementations of the technology described herein, the external Input/Output (I/O) bridge includes a flexible connector that is attached to the substrate using solder balls disposed in openings in the substrate. Thus, the bulky, male-to-female connector and/or silicon bridge are eliminated while still permitting dies disposed on the substrate to be coupled together.

One feature of the technology described herein is that the Input/Output (I/O) bridge is assembled using a Tape Automated Bonding (TAB). As a result, there are only two bonding steps: (1) fabricating the Input/Output (I/O) bridge and (2) bonding the Input/Output (I/O) bridge to the substrate.

Another feature of the technology described herein is that because the Input/Output (I/O) bridge includes solder bumps that mate to a substrate there are no plated through holes, vias, sockets, etc., that must be aligned. This feature thus tends to minimize signal discontinuities.

A further feature of the technology described herein is that the bill of materials is reduced because plugs, receptacles, and silicon bridges are not used to couple dies together on the substrate. Eliminating plugs, receptacles, and silicon bridges also makes the Input/Output (I/O) bridge and the packaging for the Input/Output (I/O) bridge less bulky.

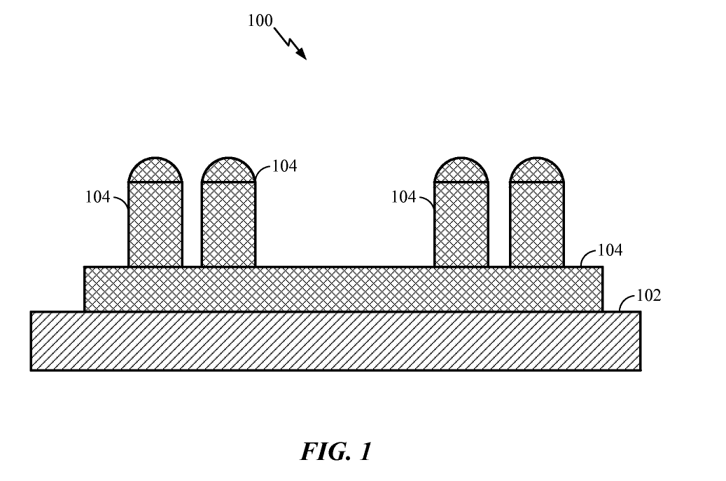

FIG. 1 is a cross-sectional representation of a flexible connector 100 for an Input/Output (I/O) bridge according to one or more implementations of the technology described herein. The illustrated flexible connector 100 includes an insulating material 102. Interconnects 104 are disposed on the insulating material 102. A routing layer 106 is disposed between interconnects 104 and the insulating material 102. A high speed Input/Output (I/O) signal path 114 is disposed in the routing layer 106

In one or more implementations, the flexible connector 100 is fabricated using a flexible tape substrate manufacturing process in which the routing layer 106 is formed first on the insulating material 102 and then interconnects 104 are fabricated on the routing layer 106.

The illustrated insulating material 102 has a first side 110 and a second side 112. The insulating material 102 may keep electrical signals in interconnects 104 from electrically interacting with any circuitry on the second side 112.

In one or more implementations, insulating material 102 may be a dielectric material made of polymer material, such as polyimide. Or course, any suitable dielectric material may be used for the insulating material 102.

The illustrated interconnects 104 are configured to couple electrical signals to a package substrate. In one or more implementations, interconnects 104 are used to align the flexible connector 100 to a package substrate so that signal discontinuities are reduced.

In one or more implementations, interconnects 104 may be made from copper or other suitable metal or conductive material. Bonding sites for interconnects 104 may be connected to electrical conductors (e.g., input/output (I/O) signal path, power plane, ground plane) on the routing layer 106. Interconnects 104 may be electrodeposited on the routing layer. Although interconnects 104 are shown to be shaped in the form of a pillar with balls formed over the pillars, interconnects 104 may be any other suitable shape. Moreover, interconnects 104 need not have balls formed over the interconnect 104.

The illustrated routing layer 106 is a high speed input/output signal path that routes electrical signals to one or more signal paths on a package substrate.

The routing layer 106 may be made from copper or other suitable metal or conductive material. The routing layer 106 may be electrodeposited on the insulating material 102 or attached to the insulating material 102 using adhesives. The patterns of interconnects 104 and routing layer 106 may be imaged onto the tape by photolithography.

In one or more implementations, the flexible connector can be assembled before attaching to a die or package substrate with a simple press bonding method (e.g., thermo-compression bonding) or reflow depending on the structure of the bumps on the interconnects 104 and the insulating material 102.

The high speed Input/Output (I/O) signal path 114 route high speed signals in the routing layer 106. One advantage of this feature is that complicated embedded structures or expensive socket/connectors in the high speed input/output signal path are eliminated.

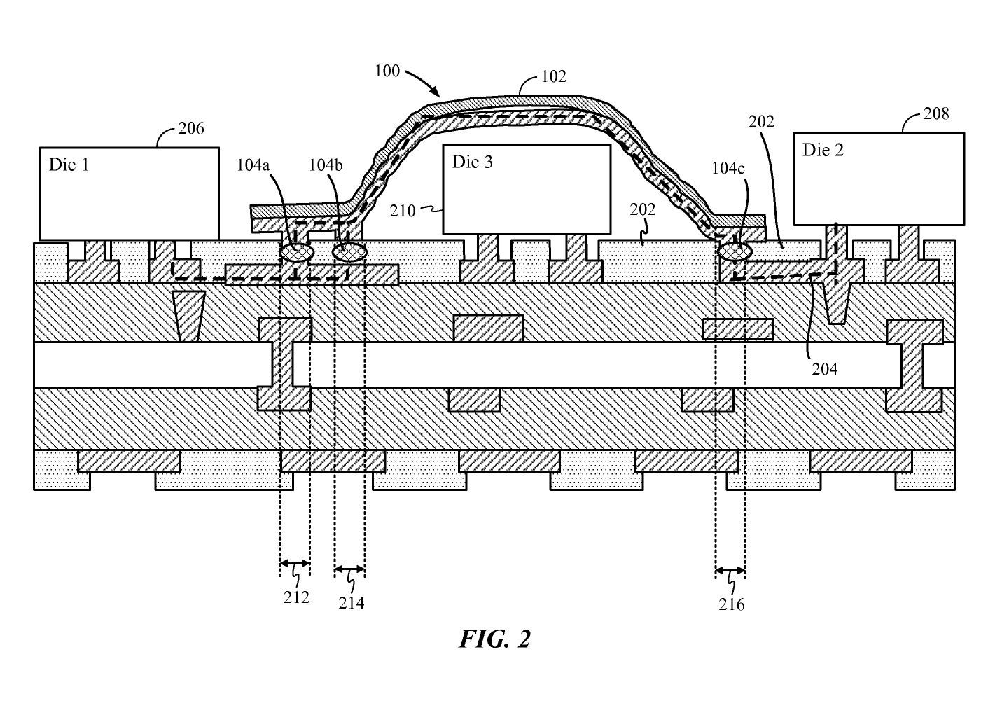

The resulting flexible connector 100 is configured to mate with circuitry disposed on a substrate. FIG. 2 is a cross-sectional representation of a semiconductor device 200 having the flexible connector 100 mounted to a substrate 202 according to one or more implementations of the technology described herein. In the illustrated implementation, the substrate 202 includes electrical conductors 204, for example, substrate routing layers 204, disposed therein.

The illustrated substrate 202 includes several dies (206, 208, 210) disposed thereon. The illustrated substrate 202 also includes several openings (represented by arrows 212, 214, 216). In one or more implementations, the number and/or size of the openings 212, 214, 216 may be determined by the number of Input/Output (I/O) signals and the pitch of the Input/Output (I/O) signal connections. Interconnects 104a, 104b, and 104c are disposed in the openings 212, 214, 216, respectively, to couple the flexible connector 100 to the substrate 202. The die 206 can then be coupled to the die 208 via the high speed Input/Output (I/O) signal path 114 and the electrical conductors 204. As discussed previously, interconnects 104 may be of various shapes and sizes, and need not have a ball as shown.

The illustrated substrate 202 may be any suitable planar wafer. For example, the substrate 202 may be a semiconductor substrate configured to support electronic circuitry. In one or more implementations, the substrate 202 may include a power plane and/or a ground plane.

The electrical conductors 204 may include an Input/Output (I/O) signal delivery path, a power plane path, and/or a ground plane path.

In one or more implementations, one or more of the dies 206, 208, 210 may include integrated circuits (ICs) and/or other active and inactive circuitry.

In one or more implementations, the openings 212, 214, 216 may be provided in the substrate 202 using known techniques. For example, the openings 212, 214, 216 may be etched, drilled, lasered, etc., in the substrate 202.

In one or more implementations, the flexible connector 100 may be mounted to the substrate 202 before the dies 206, 208, and are mounted to the substrate 202. Therefore, it does not matter if the dies 206 and 208 are misaligned because interconnects 104a, 104b, and 104c are mounted to the substrate 202 separately. That is, there are no there are no plated through holes, vias, sockets, etc., that must be aligned. Also, as illustrated, the flexible connector 100, after being mounted to the substrate 202 bypasses the die 210.

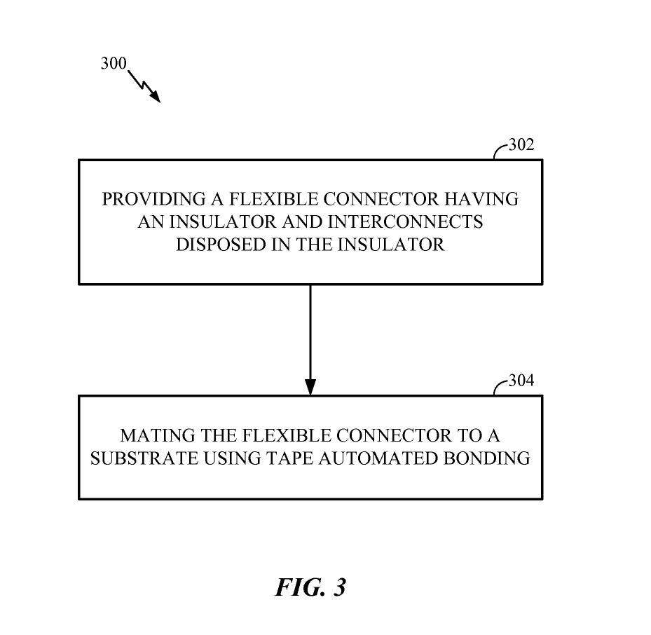

FIG. 3 is a flowchart illustrating a method 300 of making the semiconductor device 200 according to one or more implementations of the technology described herein.

In a block 302, the method 300 provides a flexible connector having an insulator and interconnects disposed in the insulator. In keeping with the illustrations in FIGS. 1 and 2, bonding sites for interconnects 104 may be connected to electrical conductors (e.g., input/output (I/O) signal path, power plane, ground plane) on the routing layer 106, which is disposed on the insulating layer 102. Interconnects 104 may be electrodeposited on the routing layer 106. The resulting assembly forms the flexible connector 100.

In a block 304, the method 300 mates the flexible connector to a substrate using a tape automated bonding (TAB) process. In keeping with the illustrations in FIGS. 1 and 2, the flexible connector 100 may be mounted to the substrate 202 such that interconnects 104 are disposed on fine conductors on the insulating material 102. This provides a mechanism to connect the flexible connector 100 to the substrate. Interconnects 104 are disposed in the several openings 212, 214, 216, before the dies 206, 208, are mounted to the substrate 202, for example.

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage, or mode of operation.

The terminology used herein is for the purpose of describing particular embodiments only and is not intended to be limiting of embodiments of the invention. As used herein, the singular forms “a,” “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof

Further, many embodiments are described in terms of sequences of actions to be performed by, for example, elements of a computing device. It will be recognized that various actions described herein can be performed by specific circuits (e.g., application specific ICs (ASICs)), by program instructions being executed by one or more processors, or by a combination of both. Additionally, these sequence of actions described herein can be considered to be embodied entirely within any form of computer-readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences, and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer-readable media embodying a method for selective renaming in a microprocessor. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps, and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A flexible connector for delivery of high speed, high density signals to a device, the flexible connector comprising:
an insulating material; and
interconnects disposed in the insulating material, wherein the interconnects are configured to mate the flexible connector in openings disposed in a substrate using solder balls.

2. The flexible connector of claim 1, wherein the interconnects are further configured to align the flexible connector to circuitry disposed in the substrate.

3. The flexible connector of claim 1, wherein the interconnects comprise copper.

4. The flexible connector of claim 1, further comprising an input/output (I/O) signal path disposed in the insulating material.

5. The flexible connector of claim 1, further comprising at least one of a power path in the substrate and a ground path in the substrate.

6. A semiconductor device assembly, comprising:
a flexible connector having:
an insulating material; and
interconnects disposed in the insulating material; and
a substrate coupled to the flexible connector, wherein the substrate includes solder balls disposed therein, and wherein the interconnects are configured to mate the flexible connector with openings disposed in the substrate using solder balls.

7. The semiconductor device assembly of claim 6, further comprising a first die disposed on the substrate and a second die disposed on the substrate, wherein the interconnects are configured to couple the first die with the second die.

8. The semiconductor device assembly of claim 6, further comprising an input/output (I/O) signal path disposed in the insulating material.

9. The semiconductor device assembly of claim 8, further comprising at least one of a power path in the substrate and a ground path in the substrate, and a signal layer in the substrate.

10. The semiconductor device assembly of claim 9, wherein the interconnects are configured to couple the at least one of a power layer, ground layer in the substrate, and a signal layer in the substrate between the first die and the second die.

11. A method of manufacturing a semiconductor device assembly, comprising:
providing a flexible connector having an insulator and interconnects disposed in the insulator; and
mating the flexible connector to openings in a substrate using at least one of tape automated bonding, reflow, and thermo-compression.

12. The method of claim 11, wherein mating the flexible connector to the substrate includes mating the flexible connector to a first set of solder balls disposed in the substrate and mating the flexible connector to a second set of solder balls, wherein mating the flexible connector to the first set of solder balls is performed separately from mating the flexible connector to the second set of solder balls.

13. The method of claim 11, further comprising disposing a first die on the substrate and a second die on the substrate, wherein the flexible connector is configured to couple the first die with the second die.

14. The method of claim 13, wherein the flexible connector includes an input/output (I/O) signal path.

15. The method of claim 14, further comprising using the flexible connector to align the input/output (I/O) signal path between the first die and the second die.

16. The method of claim 11, further comprising an input/output (I/O) path that couples at least one of the power layer and a ground layer between the first die and the second die.

17. The method of claim 11, wherein the interconnects comprise copper.

18. The method of claim 11, wherein the insulator comprises a polyimide.

19. The method of claim 11, wherein the flexible connector is mated to the substrate using at least one of tape automated bonding, reflow, and thermo-compression.
